(19) United States
(12) Patent Application Publication
(10) Pub. No.: US 2010/0297783 A1
(43) Pub. Date: Nov. 25, 2010

(54) Plasma Processing Method

(76) Inventors: Shoji IKUHARA, Hikari-shi (JP); Daisuke Shiraishi, Hikari-shi (JP); Hideyuki Yamamoto, Kudamatsu-shi (JP); Akira Kagoshima, Kudamatsu-shi (JP); Hiromichi Enami, Tokyo (JP); Yosuke Karashima, Kudamatsu-shi (JP); Eiji Matsumoto, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/849,233

(22) Filed: Aug. 3, 2010

Related U.S. Application Data
(62) Division of application No. 12/699,382, filed on Feb. 3, 2010.
Application No. 12/699,382 is a continuation of application No. 11/199,234, filed on Aug. 9, 2005, now abandoned.

(30) Foreign Application Priority Data
May 17, 2005 (JP) 2005-144043

(51) Int. Cl. H01L 21/302

(52) U.S. Cl. 438/5; 257/E21.214

(57) ABSTRACT

A method for performing a plasma process using a plasma processing apparatus which includes a vacuum process chamber, an exhaust device, a mass flow controller supplying a process gas, a stage electrode which receives and holds a workpiece by adsorption, a transfer device, and a high-frequency electrical source. The method includes a first step of performing the plasma process for the workpiece in the vacuum process chamber by a corresponding recipe of predetermined recipes, a second step of acquiring apparatus parameters showing the condition of the plasma processing apparatus when a specific recipe of the predetermined recipes is executed to diagnose whether the condition of the plasma processing apparatus is good or not based on the acquired apparatus parameters.

### CROSS REFERENCE TO RELATED APPLICATION

This application is a divisional application of U.S. Application Serial No. 12/699,382, filed Feb. 3, 2010, which is a continuation application of U.S. application Ser. No. 11/199,234, filed Aug. 9, 2005, now abandoned, in which claims directed to method and to apparatus were subject to a restriction requirement, the contents of which are incorporated herein by reference.

The present application is based on and claims priority of Japanese patent application No. 2005-144043 filed on May 17, 2005, the entire contents of which are hereby incorporated by reference.

### BACKGROUND OF THE INVENTION

1. Field of the Invention

The present invention relates to plasma processing apparatuses, and more particularly, relates to a plasma processing apparatus having a self-diagnostic function.

2. Description of the Related Art

For example, according to Japanese Unexamined Patent Application Publication No. 2004-152999, a plasma processing apparatus has been disclosed which can detect incorrect operation at an early stage and specify the causes thereof by the following procedure. That is, in the plasma processing apparatus described above, impedances and process speeds are measured when the such as high-frequency electrical power and gas conditions, are changed so that a relational curve therebetween is formed beforehand, and the electrical power conditions are measured after maintenance so as to determine whether the measured data are within a predetermined range or not.

In addition, according to Japanese Unexamined Patent Application Publication No. 2002-73158, a monitor and self-diagnostic system has been disclosed which has a field monitoring server and a remote monitoring terminal, the field monitoring server collecting real-time operation data of industrial apparatuses and storing them in accordance with a predetermined editing style, the remote monitoring terminal connected to the field monitoring server with a communication cable, reading the stored operation data of the industrial apparatuses in accordance with a predetermined editing style, and monitoring and diagnosing operation conditions of the respective apparatuses.

In semiconductor device manufacturing, periodical diagnosis of apparatus conditions is necessarily performed in order to maintain an uptime ratio thereof, and it has been believed that so-called preventive maintenance is particularly important in which the change in condition of an apparatus is detected before incorrect operation occurs. However, according to the related techniques described above, for preventive maintenance, it has been very difficult to detect incorrect operation while the apparatus is being operated, and as a result, inspection is necessarily performed after the apparatus is temporarily stopped; hence, the uptime ratio of the apparatus is inevitably decreased.

The reason the preventive maintenance is difficult to perform while an apparatus is being operated is that the apparatus condition is changed in accordance with change in condition of wafers which are being processed. For example, the pressure of an etching chamber, which forms a semiconductor device manufacturing apparatus, is changed in accordance with the change in condition of reaction between an etching gas and a film, which is provided on a surface of a substrate such as a wafer and is to be etched by the etching gas, and when the film is entirely etched away, since the reaction caused by the etching gas is stopped, a phenomenon occurs in which the pressure in the process chamber is increased (or decreased).

The same thing can be said for conditions of other apparatuses, and for example, an electrical source voltage (Vpp voltage) for plasma generation, plasma emission, or the like reflecting the plasma impedance is changed as etching reaction proceeds. In addition, a film to be etched is generally provided on the front surface of a substrate; however, when being formed by deposition, the film is likely to be also deposited on the back side of the substrate in many cases, and depending on the amount of the film deposited on the back side, a force electrostatically adsorbing the substrate is changed.

Hence, in preventive maintenance heretofore performed, after the operation of an apparatus is temporarily stopped, a specific sequence is carried out while workpieces are not being processed, so that the change in apparatus condition is detected. While the preventive maintenance as described above is performed, the operation of the apparatus must be stopped, and as a result, the uptime ratio thereof is unavoidably decreased.

### SUMMARY OF THE INVENTION

Accordingly, in consideration of the problems described above, the present invention was made, and an object of the present invention is to provide a preventive maintenance technique capable of diagnosing apparatus conditions without serious decrease in uptime ratio.

To this end, the present invention has the following structure.

A plasma processing apparatus of the present invention comprises: a plasma processing main frame and an apparatus controller controlling the plasma processing main frame in accordance with a predetermined procedure, the plasma processing main frame comprising: a vacuum process chamber; an exhaust device evacuating the vacuum process chamber; a mass flow controller supplying a process gas into the vacuum process chamber; a stage electrode receiving a workpiece in the vacuum process chamber and holding it by adsorption; a high-frequency electrical source applying a high-frequency electrical power to the supplied process gas to generate plasma; and a transfer device placing the workpiece on the stage electrode and taking out the workpiece after it is processed. In the plasma processing apparatus described above, the apparatus controller comprises a diagnosis device which acquires a plurality of recipes, one of which corresponding to the workpiece being applied thereto, and apparatus parameters of the plasma processing apparatus when a specific recipe of said plurality of recipes is executed and which diagnoses whether the condition of the plasma processing main frame is good or not based on the acquired apparatus parameters.

According to the present invention, since the plasma processing apparatus has the structure described above, a preventive maintenance technique can be provided which can diagnose the condition of the apparatus without causing a serious decrease in uptime ratio.

### BRIEF DESCRIPTION OF THE DRAWINGS

FIG. 1 is a view illustrating the structure of a plasma processing apparatus according to one embodiment of the present invention;

FIG. 2A is a flowchart illustrating a process of a plasma processing main frame;

FIG. 2B is a flowchart illustrating a process of a diagnosis device;

FIG. 2C is a flowchart illustrating a process of a diagnosis program;

FIG. 3A is a view illustrating diagnosis of a mass flow controller according to a first example;

FIG. 3B is a graph showing the relationship of a process chamber pressure with time according to the first example;

FIG. 3C is a graph showing the relationship of a process chamber pressure with time according to the first example;

FIG. 4A is a flowchart illustrating a diagnosis process according to the first example;

FIG. 4B is a table showing a recipe used in the first example;

FIG. 4C is an example of a table of registered and permissible values of the first example;

FIG. 5A is a view illustrating diagnosis of an exhaust capability of a vacuum exhaust device according to a second example;

FIG. 5B is a graph showing the relationship of a gas flow rate and a suction pressure with time according to the second example;

FIG. 6A is a flowchart illustrating a diagnosis process according to the second example;

FIG. 6B is a table showing a recipe used in the second example;

FIG. 6C is an example of a table of registered and permissible values of the second example;

FIG. 7A is a view illustrating diagnosis of an electrostatic adsorption capability according to a third example;

FIG. 7B is a graph showing the relationship of a cooling gas pressure with time according to the third example;

FIG. 7C is a graph showing the relationship of a gas flow rate with time according to the third example;

FIG. 8A is a flowchart illustrating a diagnosis process according to the third example;

FIG. 8B is a table showing a recipe used in the third example;

FIG. 8C is an example of a table of registered and permissible values of the third example;

FIG. 9A is a view illustrating diagnosis of a deposition amount in a process chamber according to a fourth example;

FIG. 9B is a graph showing the relationship between the emission intensity and the wavelength according to the fourth example;

FIG. 9C is a graph showing the relationship between the emission intensity and the number of processed wafers according to the fourth example;

FIG. 9D is a graph showing the relationship between the emission intensity and the number of processed wafers according to the fourth example;

FIG. 9E is a graph showing the relationship between a deposition index and the number of processed wafers according to the fourth example;

FIG. 10A is a flowchart illustrating a diagnosis process according to the fourth example;

FIG. 10B is a table showing a recipe used in the fourth example;

FIG. 10C is an example of a table of registered and permissible values of the fourth example;

FIG. 11A is a view illustrating diagnosis of the degree of wear of a component according to a fifth example;

FIG. 11B is a schematic view showing the relationship among process parameters for the diagnosis the degree of wear of a component according to the fifth example;

FIG. 12A is a table showing a recipe used in the fifth example;

FIG. 12B is an example of a table of registered and permissible values of the fifth example;

FIGS. 13A and 13B are flowcharts illustrating a diagnosis process according to the fifth example;

FIG. 14A is a view illustrating diagnosis of a leak-gas amount and an outgas amount according to a sixth example;

FIG. 14B is a graph showing the relationship between the emission intensity and the wavelength according to the sixth example;

FIG. 14C is a graph showing the relationship between the pressure inside a process chamber and the time according to the sixth example;

FIG. 15A is a table showing a recipe used in the sixth example;

FIG. 15B is an example of a table of registered and permissible values of the sixth example;

FIG. 16 is a flowchart illustrating a diagnosis process according to the sixth example;

FIG. 17A is a flowchart illustrating a diagnosis process according to a seventh example;

FIG. 17B is a table showing a recipe used in the seventh example;

FIG. 18A is a flowchart illustrating a diagnosis process according to an eighth example;

FIG. 18B is a table showing a recipe used in the eighth example;

FIG. 18C is an example of a table of registered and permissible values of the eighth example;

FIG. 19 is a table showing process parameters of the eighth example;

FIG. 20 is a table showing process parameters of the eighth example;

FIG. 21A is a flowchart showing a diagnosis process according to a ninth example;

FIG. 21B is a table showing a recipe used in the ninth example;

FIG. 21C is an example of a table of registered and permissible values of the ninth example; and

FIG. 22 is a table showing summaries of the respective examples.

### DESCRIPTION OF THE PREFERRED EMBODIMENTS

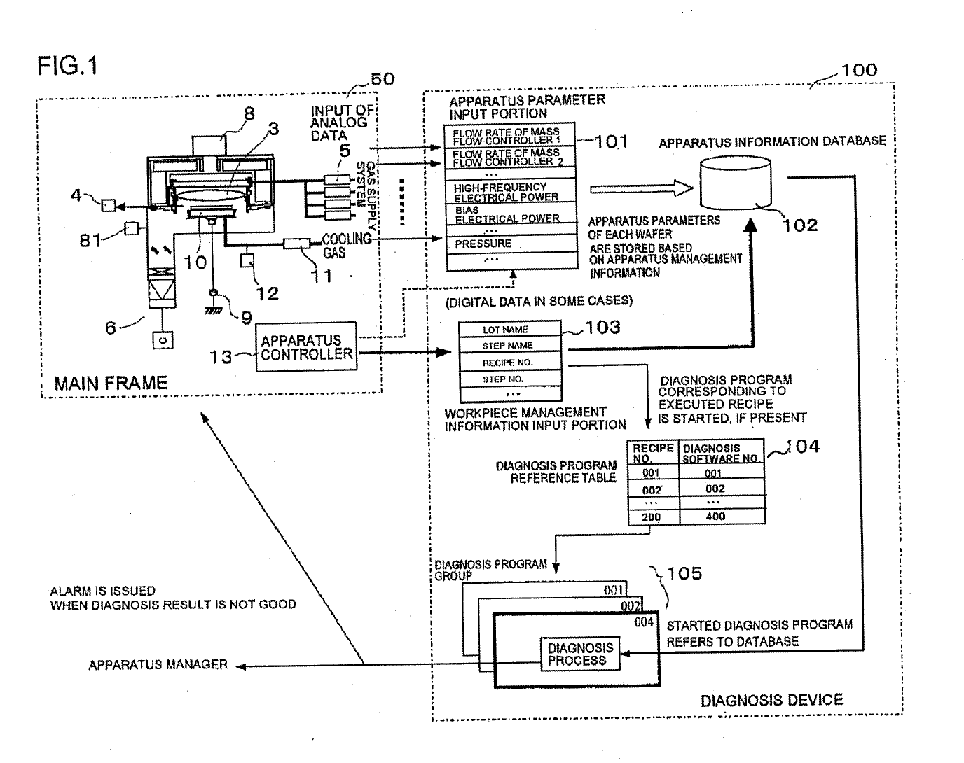

Hereinafter, an embodiment of the present invention will be described with reference to accompanying figures. FIG. 1 is a view illustrating the structure of a plasma processing apparatus according to the embodiment of the present invention.

In FIG. 1, when a workpiece 2 such as a wafer which is to be processed is placed on a stage electrode 10 in a vacuum process chamber 1, an etching gas is supplied at a constant flow rate into the vacuum process chamber 1 from a gas supply system 4 via a mass flow controller 5 which controls the above flow rate. The gas thus supplied is evacuated from an exhaust device 6. In this step, by adjusting the opening of a variable conductance valve 7 placed in an exhaust path while the pressure inside the vacuum process chamber 1 is monitored by a pressure gage 81, the pressure inside the vacuum process chamber 1 can be maintained at a predetermined level.

Subsequently, plasma 3 is excited by a high-frequency electrical source 8 for plasma generation, and in addition, by a bias high-frequency electrical source 9, ions generated in the plasma are pulled onto the surface of the workpiece 2, so that etching proceeds. In etching, the temperature of the workpiece 2 in the plasma 3 is increased by heat generated therein. Hence, a cooling gas is supplied to the back side of the workpiece 2 via a mass flow controller 11. The pressure of the cooling gas is monitored by a pressure gage 12 and is maintained at a predetermined level.

An apparatus controller 13 controls a plasma processing main frame 50 in accordance with a predetermined procedure and processes workpieces by respective recipes, the workpieces being carried in the process chamber 1 by a transfer device not shown in the figure. The apparatus controller 13 stores a plurality of recipes and acquires apparatus parameters of the plasma processing main frame 50 when specific recipes (such as a diagnosis recipe using a dummy wafer) of said plurality of stored recipes are executed, so that the apparatus parameters thus obtained are stored in an apparatus parameter input portion 101 (in this case, in the apparatus parameter input portion 101, apparatus parameters obtained when all recipes are executed may also be stored).

In this case, the apparatus controller 13 stores information of the workpiece 2 carried in the vacuum process chamber 1 by the transfer device and workpiece management information thereof (such as dummy wafer No., wafer No., lot name, recipe No., and the like) which specifies and manages a process (recipe) to be executed for this workpiece in a workpiece management information input portion 103.

The apparatus parameters stored in the apparatus parameter input portion 101 and the workpiece management information stored in the workpiece management information input portion 103 are saved in an apparatus information database 102. In this case, it is convenient when the apparatus parameters are saved based on respective workpieces stored in the workpiece management information.

Of the workpiece management information stored in the workpiece management information input portion 103, as for workpiece management information including the above specific recipes (such as a diagnosis recipe using a dummy wafer), diagnosis programs are prepared for respective specific recipes and are stored in a diagnosis program reference table 104.

When a process in accordance with the above specific recipe is performed, for example, for a dummy wafer, the apparatus controller 13 selects a diagnosis program corresponding to the specific recipe from a diagnosis program group and starts the program to diagnose the apparatus condition. In this step, as described later, after reading the apparatus parameters stored in the apparatus information database 102, the diagnosis program diagnoses the apparatus condition, displays the diagnosis result thereof, and issues an alarm when the result is abnormal.

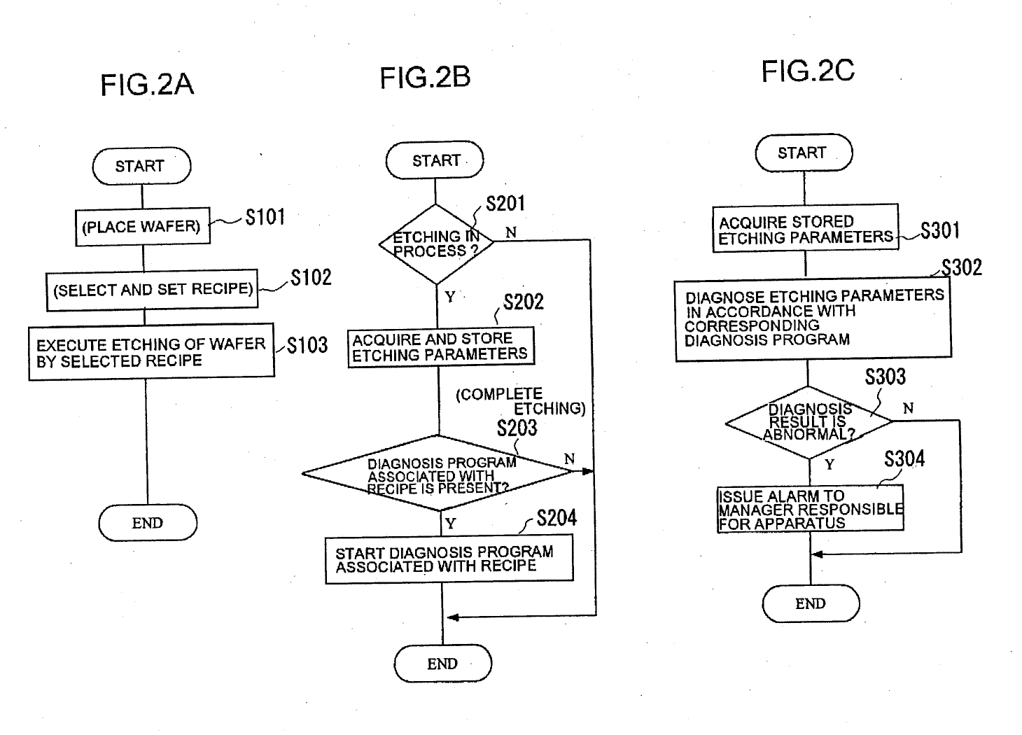

FIG. 2A is a flowchart illustrating a process of the main frame 50 of the plasma processing apparatus, FIG. 2B is a flowchart illustrating a process of a diagnosis device 100; and FIG. 2C is a flowchart illustrating a process of a diagnosis program.

As shown in FIG. 2A, in the main frame of the plasma processing apparatus, a workpiece (wafer) is first placed on the stage table in Step S101, a recipe corresponding to the workpiece is selected and set in Step S102, and the process is started in Step S103.

In FIG. 2B, in the diagnosis device 100, it is determined in Step S201 whether a process (such as an etching process) is being performed in the main frame of the plasma processing apparatus or not, and when the process is being performed, the apparatus parameters (such as etching parameters) and the workpiece management information including a dummy wafer No. wafer No, lot name, and recipe No. are acquired and stored in the apparatus information database 102 in Step S202. In Step S203, it is determined whether a diagnosis program associated with the recipe used in the main frame of the plasma processing apparatus is stored in the diagnosis program reference table or not, and when being stored, the diagnosis program is started in Step S204 for the diagnosis process.

In FIG. 2C, at the diagnosis program side, the apparatus parameters stored in the apparatus information database 102 are acquired in Step S301, and the apparatus condition is diagnosed in accordance with the diagnosis program in Step S302. In Step 303, it is determined whether the diagnosis result is abnormal or not, and when the result is abnormal, an alarm is issued indicating that the apparatus is in an abnormal state.

### Example 1

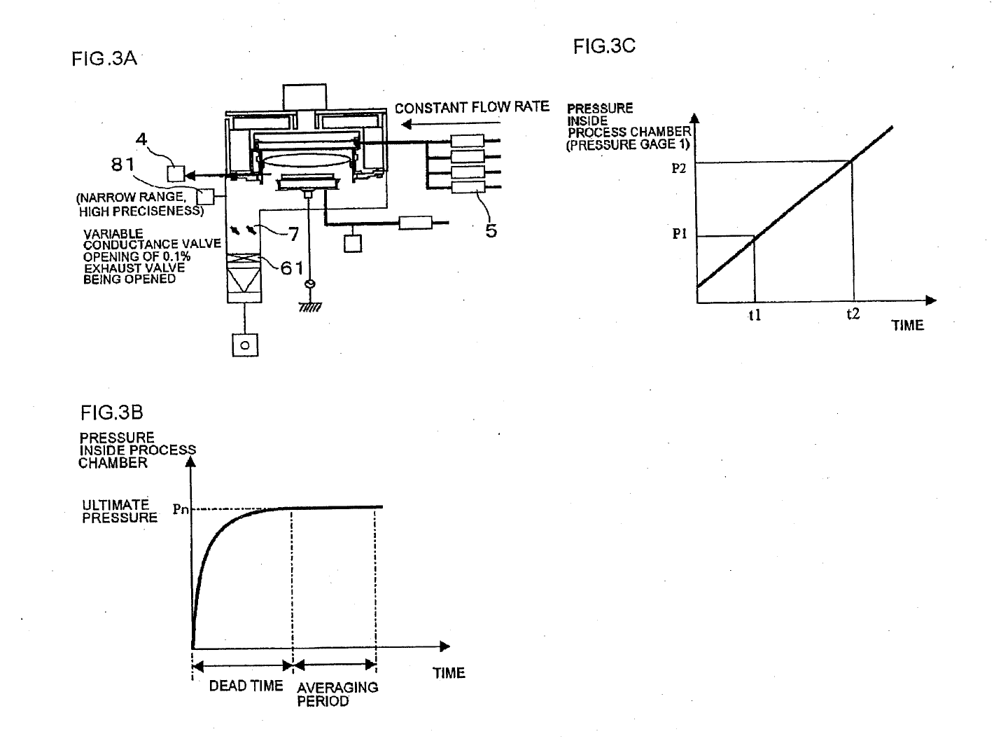

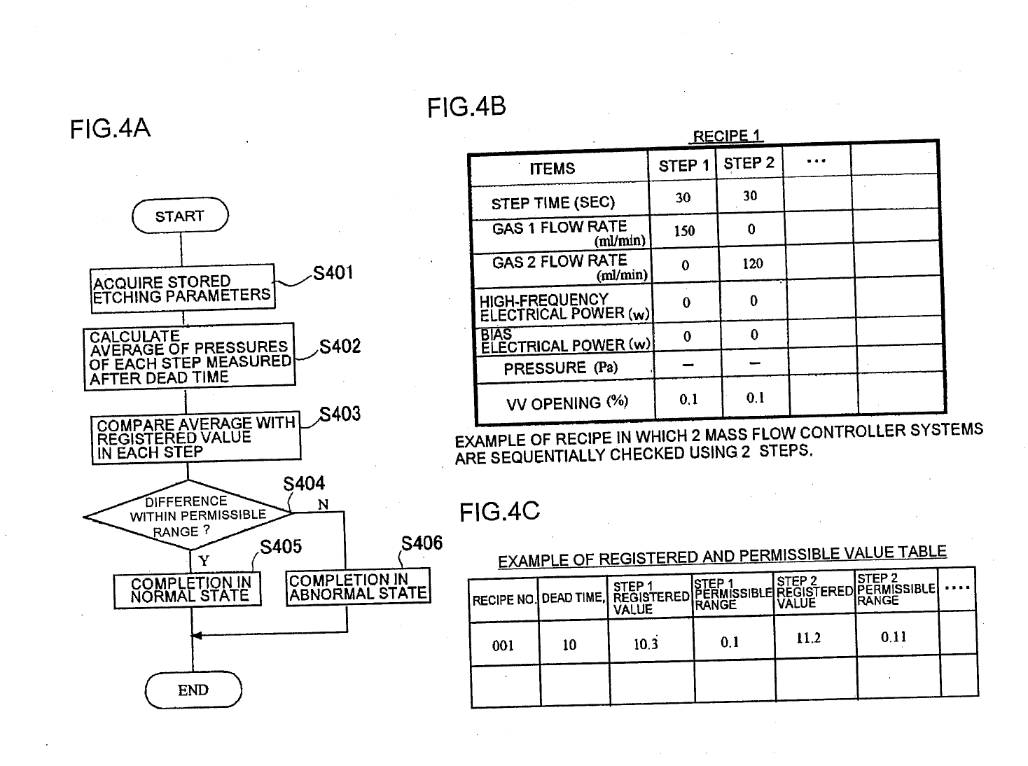

FIGS. 3A to 3C and 4A to 4C are views illustrating diagnosis of change in gas flow rate (diagnosis of change in gas flow rate via the mass flow controller 5 with time) of a first example according to the present invention. In the example shown in these figures, as described above, in addition to the main frame of the plasma processing apparatus, the diagnosis device 100 measuring process parameters of etching and recording them with time is also prepared. In this example, the diagnosis device 100 may be incorporated in the main frame 50.

The parameters described above are software values of the apparatus including output values of respective devices such as an output value of a plasma electrical source, input values such as a measured value of a pressure gage, and set values of a recipe. In general, since the aforementioned process parameters are monitored at the main frame side of the apparatus in many cases, without additionally providing measurement means, the parameters may be received as the data from the main frame side. In addition, as described above, the diagnosis program is automatically started in accordance with a recipe No. which is processed, so that measured process parameters are analyzed. In accordance with the diagnosis result, this program may have a function to issue an alarm to a host computer managing the main frame and the apparatus.

In this example, the diagnosis program which is started in accordance with the recipe No. is described; however, the diagnosis program may be started in accordance with the recipe name instead of the recipe No. or may be started associated with datum such as the lot No. or lot name which is given to a lot to be processed. The importance is that the structure is reliably formed in which when an object diagnosis recipe is executed, a diagnosis program associated therewith is automatically executed.

Next, with reference to FIGS. 4A and 4B, the procedure of a preventive maintenance process will be described. This procedure is executed while the apparatus is operated. However, while an actual workpiece (wafer) is being processed, the change in gas flow rate is difficult to check. One of the reasons for this relates to a pressure range. Although an etching process pressure tends to be decreased concomitant with the advancement of micro-fabrication technique, since there is a limit of the resolution of a pressure gage, when the change in pressure is close to the level of the resolution, the S/N ratio is degraded, and as a result, the change in pressure cannot be discriminated from noises. The other reason is the change in pressure during etching. As the etching proceeds, a chemical composition, ion ratio, temperature, and the like are being changed. Hence, it is difficult to define the condition regarded as the standard. By the reasons described above, the measurement of flow rates is difficult to perform while workpieces (wafers) are being processed for production.

Hence, when the change in gas flow rate is checked, a dummy workpiece (dummy wafer) is used. As dummy wafers, a lot for the purpose of preventive maintenance may be supplied, or dummy wafers may be supplied between lots which are processed for production. As described above, the dummy wafers are processed only under specific recipe (diagnosis recipe) conditions. In this case, since an object of this recipe (recipe 1 shown in FIG. 4(b)) is to measure a gas flow rate, a gas is supplied at a predetermined gas flow rate but plasma is not generated.

Next, the variable conductance valve 7 is narrowed to a predetermined level (such as 0.1%) so that the pressure inside the process chamber 1 is increased to an approximately full scale level of the process-chamber pressure gage 81. In this example, the gas flow rate of the recipe and the opening of the variable conductance valve 7 are optimized beforehand, and the ultimate pressure at the initial apparatus condition is recorded.

Next, the diagnosis recipe is executed during operation of the apparatus. Since this recipe is executed as a part of automatic operation of the apparatus, it is not necessary to stop the operation of the apparatus. In addition, since production can be started immediately after the execution of this recipe, only the execution time of this recipe is a downtime (non-operation time) of the apparatus.

Simultaneously with the execution of this recipe, the process parameters of the apparatus are recorded by a recording device. After the execution of the recipe, when this recipe No. is registered beforehand, a diagnosis program which is also registered is started in the diagnosis device. This program executes diagnosis operation based on the recorded process parameters described above.

In this case, the result of the execution of the diagnosis recipe, that is, the ultimate pressure of the process chamber is measured which is obtained at a predetermined valve opening of the variable conductance valve and at a predetermined gas flow rate. In order to eliminate noises, the pressure is obtained by averaging pressures in a stable period during the execution of the recipe.

FIG. 3B is a view showing the change in pressure inside the process chamber 1 with time. An ultimate pressure Pn shown in the figure is compared to the value registered beforehand as a normal value, and when the deviation is generated, an alarm is issued. A manager responsible for the apparatus, who receives the alarm, again performs calibration by a build-up method, which will be described later, or using a dedicated flow rate calibration meter or the like.

A particular calibration capability of the check method described above is to be considered. Although the full scale of a general pressure gage is approximately 13 Pa in many cases, it is assumed that the gas flow rate (Q) and the opening of the variable conductance valve are optimized so that the pressure (P) is increased to approximately 10 Pa. Under the conditions described above, when 1% of the gas flow rate is changed, from the equation P=Q×V, the pressure inside the process chamber is also changed by 1% (in the above equation, V indicates the volume of the process chamber). In this case, since the change is 1% of 10 Pa, the change of pressure is 0.1 Pa. Since this value is approximately less than 1% of the full scale of the pressure gage, it is believed that this value is sufficiently large to be recognized as the deviation. That is, since a change of 1% of an actual flow rate via the mass flow controller can be detected by the method described above, as a daily check for preventive maintenance, it is said that the method described above is a satisfactory level.

FIG. 4A is a flowchart illustrating a process of the diagnosis program. First, in Step S401, the apparatus parameters such as etching parameters stored in the apparatus information database are acquired, and in Step S402, the average values of pressures measured after the dead time are calculated for respective steps. In Step S403, the average values of the respective steps are compared with the registered values. In Step S404, it is determined in each step whether the difference between the average value and the registered value is within a permissible range or not, and when the difference is not within the permissible range, an alarm indicating abnormality is issued.

FIG. 4B is a table showing a recipe 1 having two steps, the results of which are processed in Steps S402 and S403. As shown in the figure, a gas 1 is supplied in step 1, and a gas 2 is supplied in step 2. Hence, two mass flow controllers supplying the gas 1 and the gas 2 can be checked. In addition, FIG. 4C is a table listing the registered values and the permissible ranges of steps 1 and 2 (the tables listing the registered values and the permissible values are preferably obtained beforehand by experiments or the like).

The set values of the gas flow rates in steps 1 and 2 are each adjusted so that the pressure inside the process chamber is close to the full scale of the pressure gage at this set flow rate and this opening of the variable conductance valve. Since the absolute value of the check result is not required in the present invention, the maximum flow rate is not always necessary, and an optimum value for checking operation may be used as the set value. The results of the respective etching steps are registered in the apparatus information database 102 as described above, and the diagnosis program acquires the process parameters listed in the registered and permissible value table from the database.

In this example, from the pressures measured in steps 1 and 2, the averages thereof are obtained after the dead time. The averaged values are compared to the respective registered values, and when the results are outsides the permissible ranges, the gas flow rates are determined abnormal (defects of mass flow controller), so that an alarm indicating abnormality is issued.

### Comparative Example

While the flow rate of the mass flow controller 5 is maintained constant, an exhaust valve 61 is closed, and the increase in pressure inside the process chamber 1 is monitored. FIG. 3C is a graph showing the increased in pressure in this case. At a time represented by t1 at which a predetermined pressure P1 is obtained, the time required for increase in pressure is measured. When the volume of the process chamber 1 is precisely obtained, the actual flow rate of the mass flow controller can be obtained. This method is a so-called build-up method, and in order to carry out this method, the operation of the apparatus must be temporarily stopped.

Next, a method for checking the flow rate of the mass flow controller without stopping the operation is then considered. When the pressure and the volume of the process chamber are represented by P and V, respectively, s gas flow rate flowing into the process chamber is obtained by the equation Q=PN.

In general, since V is constant, it is understood that Q is proportional to the pressure P. Hence, when the pressure P is measured, the gas flow rate Q can be obtained.

According to the present invention, since the original object of preventive maintenance is to detect the change of the apparatus with time, the absolute value of the flow rate is not always required. When the change with respect to the initial flow rate is grasped, more detailed measurement may be separately performed. Hence, preventive maintenance can be performed in the case in which a pressure corresponding to a certain flow rate is recorded beforehand, and when the amount of change in pressure exceeds a predetermined value, an alarm is issued. However, as described above, it is difficult to check the change in gas flow rate while actual workpieces are being processed for production.

### Example 2

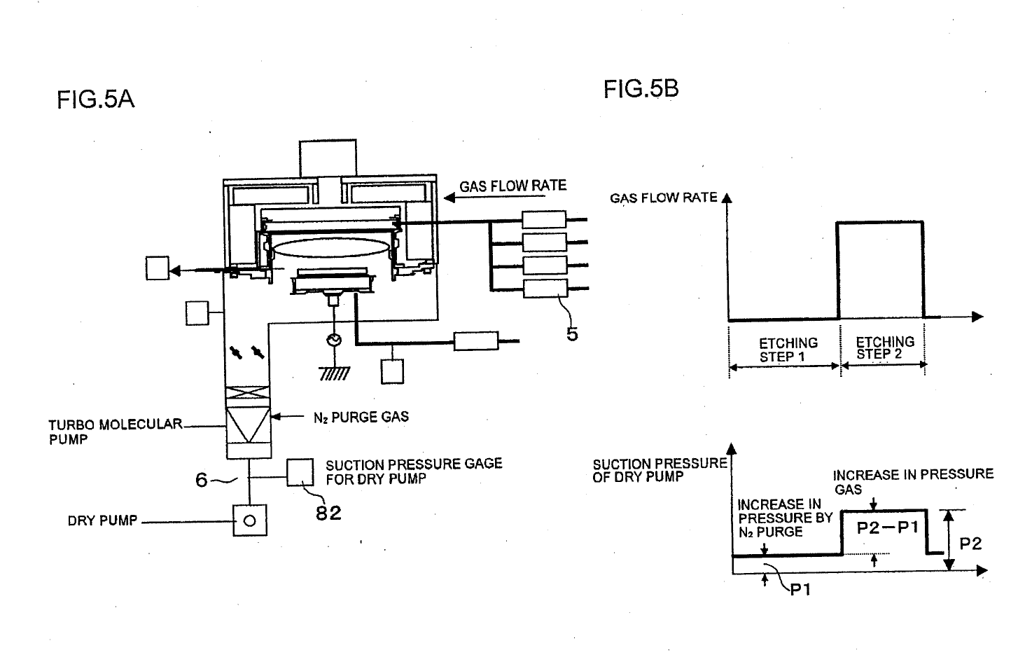

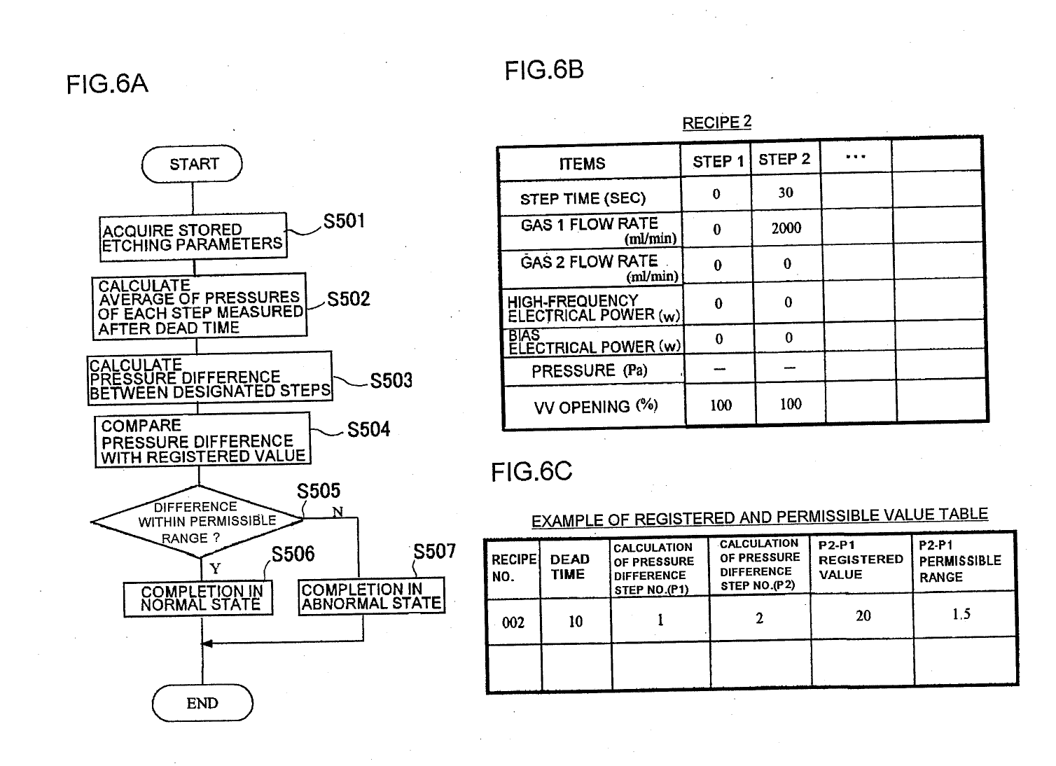

FIGS. 5A, 5B and 6A to 6C are views illustrating diagnosis of exhaust capability of a vacuum exhaust device of Example 2 according to the present invention. In Example 1 described above, the case is described based on the assumption that the exhaust capability is constant; however, in Example 2, a method for checking the exhaust capability of the vacuum exhaust device 6 will be described.

In an etching apparatus, the exhaust device 6 is generally formed of a turbo molecular pump and a dry pump. Of the pumps described above, in the turbo molecular pump, a rotor is rotated generally at a predetermined revolution speed, and under a steady state, the exhaust capability thereof is not decreased. The failure of the turbo molecular pump is caused by the stop of the rotor, and in this case, the failure mode is characterized in that the exhaust capability is rapidly decreased to zero. That is, in the case of the dry pump, the exhaust capability thereof is decreased with time, and when it is decreased to a certain level or less, the exhaust capability of the entire system becomes insufficient.

The exhaust capability of the dry pump is generally evaluated by an exhaust time measured from the atmospheric pressure; however, for this evaluation, the operation of the apparatus must be stopped. In addition, the exhaust capability can be estimated to a certain extent when the increase in pressure is monitored by a vacuum gage provided between the dry pump and the turbo molecular pump while a predetermined amount of a gas is supplied; however, it is also difficult to perform this measurement during normal operation.

Among the reasons for this, first, since in an apparatus using a corrosive reactive gas, purging is performed by a nitrogen gas in order to prevent corrosion of a pump system, and the amount of a purging gas is not generally controlled, the flow rate thereof cannot be precisely grasped. Second, since the amount of an etching gas is small, the difference in total amount of gases is small between the cases in which an etching gas is supplied and is not supplied, and in addition, since the flow rate of an etching gas is set by the recipe, the degree of increase in pressure cannot be estimated.

Accordingly, in this example, the exhaust capability is checked by the following method. First, under the condition in which a gas is not supplied (etching step 1 of a recipe 2 shown in FIG. 5B), a suction pressure (P1) of the dry pump is measured by a pressure gage 82 and is recorded. Next, under the condition in which a gas is supplied in an amount as large as possible (etching step 2 of a recipe 2 shown in FIG. 5B), a suction pressure (P2) of the dry pump is measured by the pressure gage 82 and is recorded.

FIG. 6A is a flowchart illustrating a process of the diagnosis program. As shown in FIG. 6B, the procedure described above can be realized when step 1 and step 2 are executed which are the same step except that the flow rate in step 1 and that in step 2 are 0 and 2,000 ml/min, respectively. By the procedure described above, after the suction pressures of the dry pump are measured, the difference in pressure is calculated which is obtained between the cases in which the gas is supplied and is not supplied. By this calculation, the increase in pressure caused by the nitrogen purge is cancelled, and only the increase in pressure caused by the process gas can be grasped. In addition, since a large amount of gas is supplied as compared to that in general etching process, this increase in pressure is large, and in addition, since the same amount of the gas is supplied at every time, this increase in pressure can be compared to that obtained in the past. Furthermore, when this value is compared with the registered value shown in FIG. 6C, the change in exhaust capability with time can be evaluated.

As shown in FIG. 6A, in Step S501, the apparatus parameters such as etching parameters stored in the apparatus information database are first acquired, and in Step S502, the averages for the respective steps are calculated from pressures measured by the pressure gages after the dead time. In Step S503, the difference in pressure (P2−P1) between etching steps 1 and 2 is calculated, and this difference is compared with the registered value in Step S504. In Step S505, it is determined whether the above difference in pressure is within the permissible range or not, and when the difference is outside the permissible range, a signal indicating abnormality is issued.

### Example 3

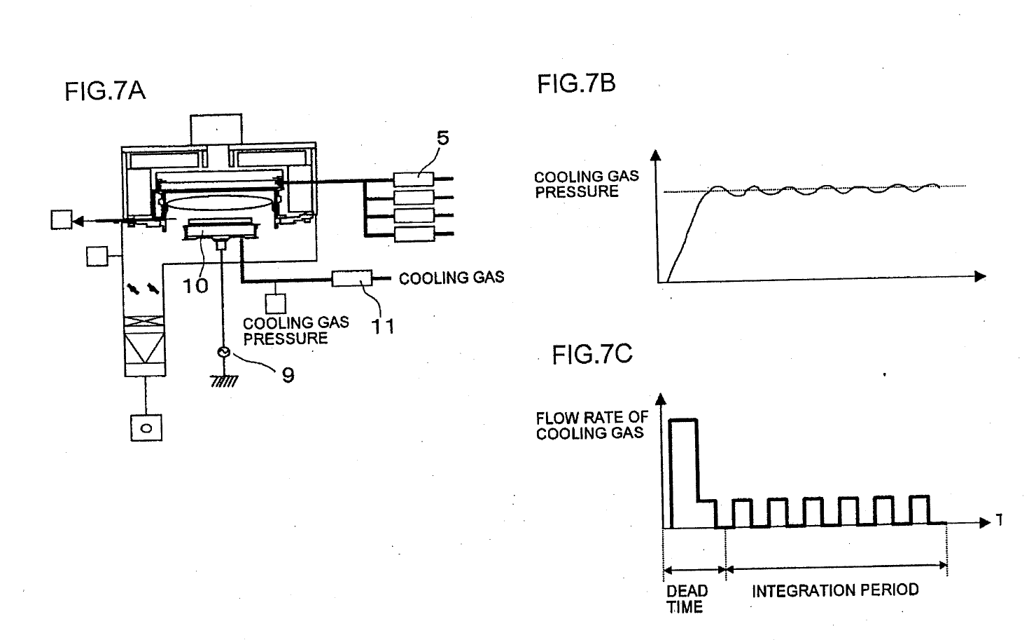

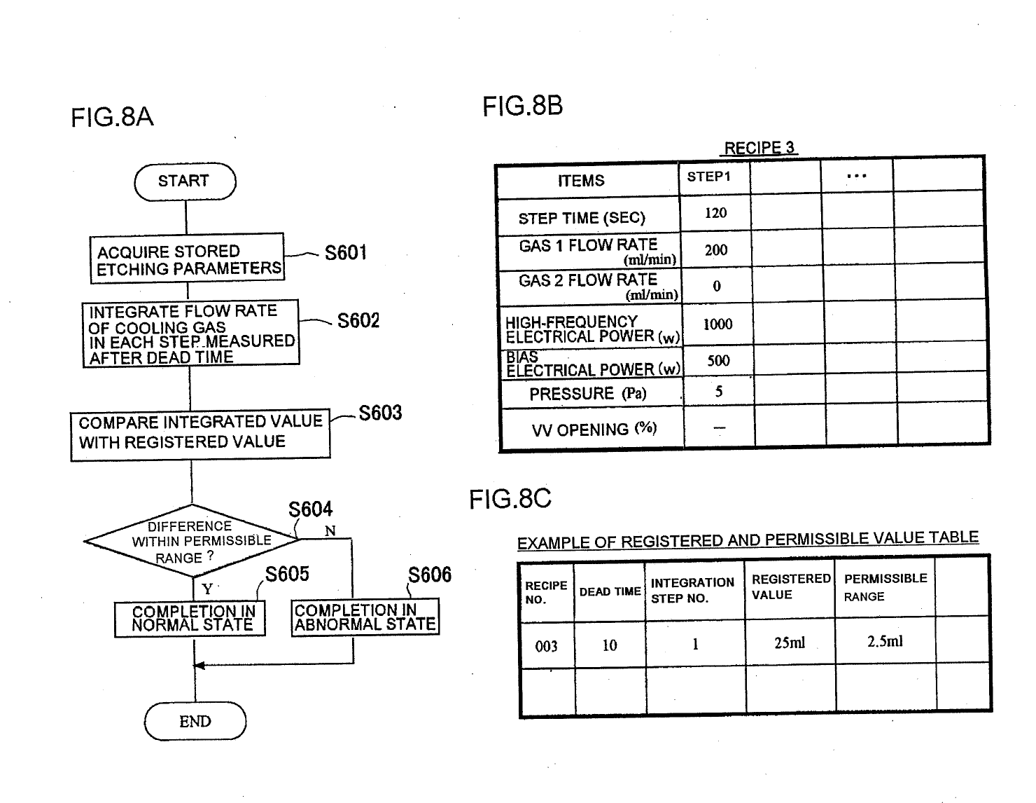

FIGS. 7A to 7B and 8A to 8C are views illustrating diagnosis of electrostatic adsorption capability of Example 3 according to the present invention. A cooling gas is supplied to the back side of a workpiece which is electrostatically adsorbed on the stage electrode 10, and the pressure of the cooling gas is maintained at a predetermined pressure. Accordingly, heat exchange between the workpiece and a holder (the surface of the stage electrode) can be stabilized, and as a result, the increase in temperature thereof can be suppressed.

The workpiece directly receives energy from plasma by a bias voltage. Since being exposed to high energy, the holder is a part whose properties are liable to be changed with time. For example, etching reaction products deposit on the electrode surface, and the surface roughness and surface electrical properties of the electrode are changed. These changes with time influence the adsorption of the workpiece and the cooling properties, and when the above properties are degraded, displacement of the workpiece due to insufficient adsorption and degradation in etching performance due to insufficient cooling may occur in some cases.

As preventive maintenance, the adsorption condition of the workpiece is monitored; however, in general, the condition of a cooling gas, such as the pressure of a cooling gas, is monitored. As the gas pressure control, the following two methods may be mentioned. One method is to change the flow rate of the cooling gas, and the other method is to change the opening of the pressure control valve while the flow rate of the cooling gas is maintained constant. In both cases, when the flow rate of the cooling gas is integrated over the control period, the total gas volume which is supplied to the back side of the workpiece can be calculated. This total gas flow volume is a volume leaking between the workpiece and the holding portion, and hence when the change in total gas volume with time is measured, the change in electrostatic adsorption properties can be detected.

Also in this case, since variation among workpieces used for production exists, and the amount of a film material deposited on the back side of the workpiece is not known, conditions which define the total gas flow volume during production operation cannot be precisely determined, the film material being supplied to form a film on the front surface of the workpiece.

Hence, in this example, a dummy wafer is used as the workpiece. Accordingly, the total gas flow volume can be reproducibly obtained from measurement to measurement.

FIGS. 7B and 7C are views illustrating the pressure and the flow rate of the cooling gas supplied to the back side of the workpiece. As shown in FIG. 7C, when the flow rate of the cooling gas is integrated over a predetermined period as shown by an integration period, although the flow rate pulsates, the change with time can be precisely detected.

FIGS. 8A to 8C are views illustrating the diagnosis program. As shown in FIG. 8A, in Step S601, the apparatus parameters such as etching parameters stored in the apparatus information database are first acquired, and in Step S602, the flow rate of the cooling gas measured after the dead time is integrated for each step. In Step S603, the integrated value obtained by integration is compared with the registered value shown in FIG. 8C. In Step S604, it is determined whether the difference between the integrated value and the registered value is within the permissible range or not, and when the difference is outside the permissible range, a signal indicating abnormality is issued.

### Example 4

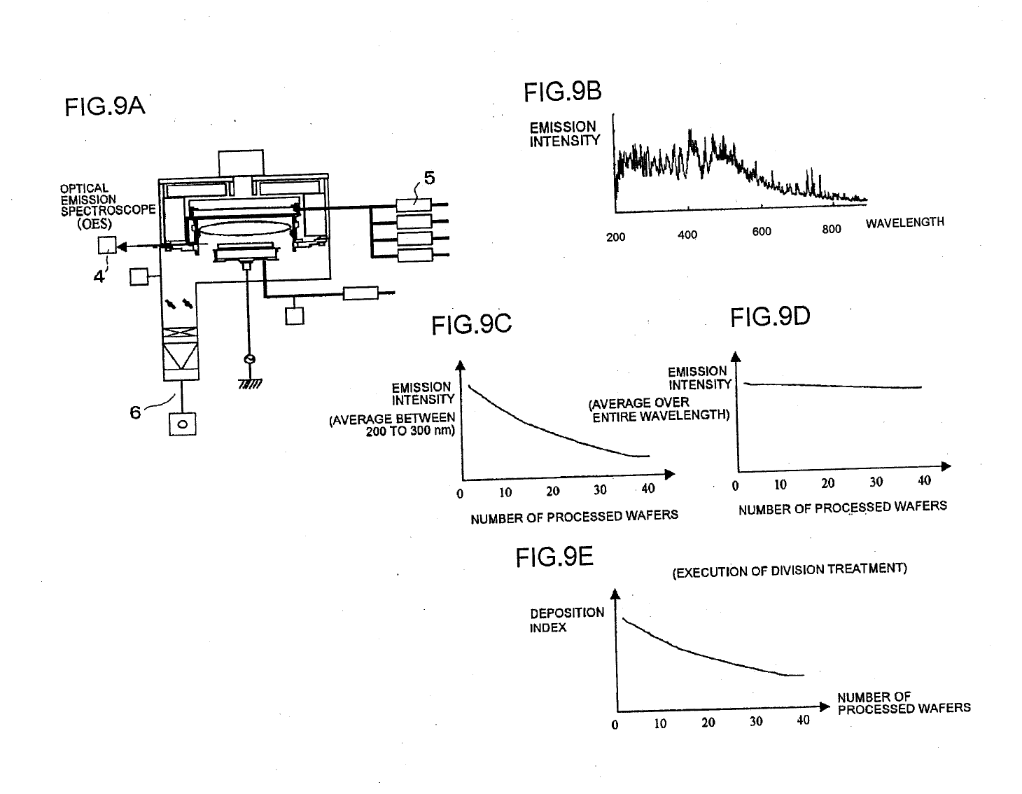

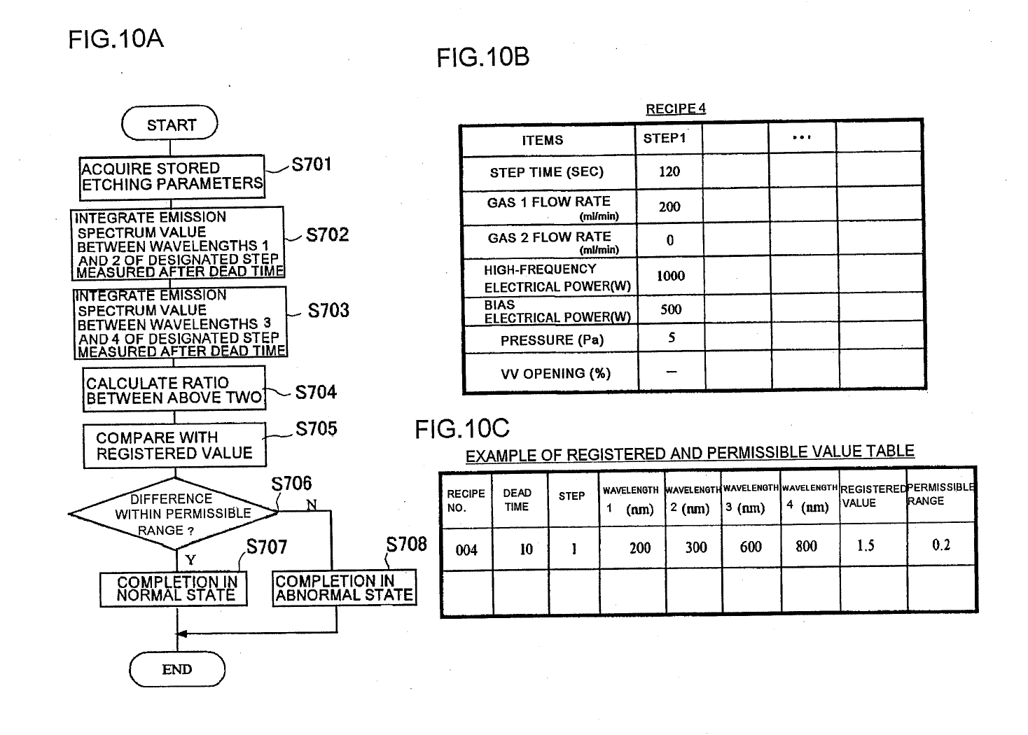

FIGS. 9A to 9E and 10A to 10C are views illustrating diagnosis of a deposition amount in the process chamber of a fourth example according to the present invention. From the fact in that plasma emission in etching is used for determining the end point, it is understood that the emission condition is changed as etching proceeds.

In this example, by using a dummy wafer, the emission in discharge by a specific recipe (diagnosis recipe) is monitored. Accordingly, a stable emission condition can always be obtained. The emission condition can be monitored by an optical emission spectroscope (OES) 4 through a window of an opening portion provided for the process chamber. When the emission is always monitored under the same condition as is the case of this example, the change in emission condition with time can be understood from the degree of haze of the window, and hence the deposition in the process chamber can be estimated.

As shown in FIGS. 9B to 9D, compared to the case (FIG. 9D) in which the average (over the entire range of frequency) of the entire emission intensity is obtained and is then compared with the average obtained when no deposition is performed, the influence by the deposition can be sensitively detected in the case (FIG. 9C) in which the average of the emission intensity in a short-wavelength region of 200 to 300 nm is obtained. Furthermore, when the average of the emission intensity in the region of 200 to 300 nm is divided by that in a long-wavelength region, since the value is normalized as shown in FIG. 9E, the comparison with a standard index can be performed instead of that with the average value obtained in the past. Hence, a more widely usable diagnosis method can be obtained.

FIGS. 10A to 10C are views illustrating the diagnosis program. As shown in FIG. 10A, in Step S701, the apparatus parameters stored in the apparatus information database are first acquired, and in Step S702, from the emission intensity data of a designated step obtained after the dead time, the emission spectral value between a wavelength 1 and a wavelength 2 shown in FIG. 10C is integrated. In Step S703, the emission spectral value is integrated from a wavelength 3 to a wavelength 4 shown in FIG. 10C. In Step S704, the ratio therebetween is calculated. The ratio thus obtained is compared with the registered value in Step S705, it is determined in Step S706 whether the difference is within the permissible range shown in FIG. 10C or not, and when the difference is outside the permissible range, a signal indicating abnormality is issued.

### Example 5

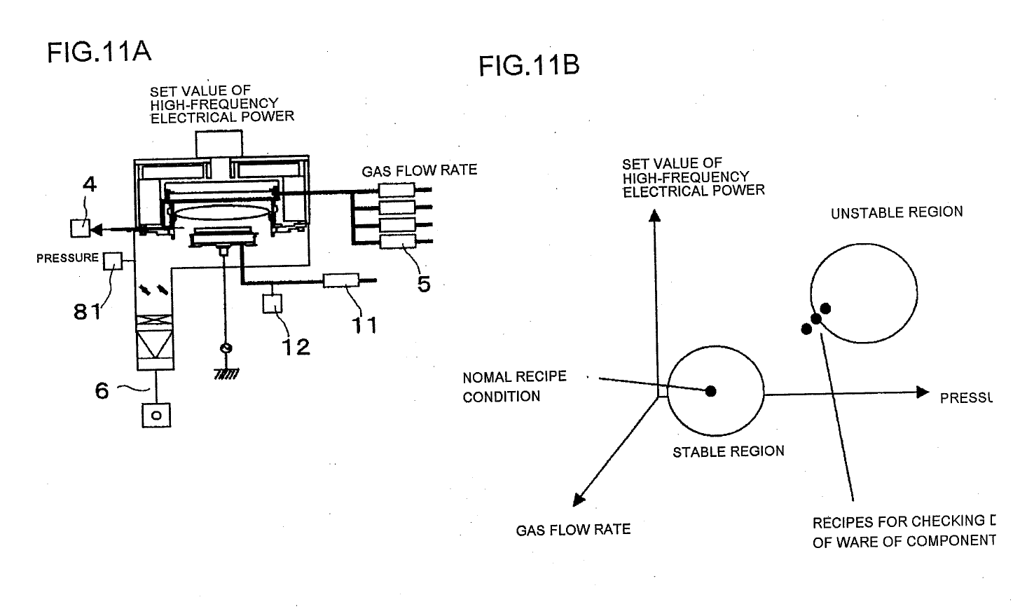

FIGS. 11A, 11B, 12A, 12B, 13A and 13B are views illustrating diagnosis of the degree of wear of components of a fifth example according to the present invention. In this example, the change in electrical discharge system with time is investigated, so that the degree of wear of components is checked.

In general, it is difficult to detect the degree of wear of components exposed to electrical discharge, and the exchange of components is performed using the total discharge time as an index in many cases. When the exchange of components is not properly performed, a local discharge phenomenon, a so-called abnormal discharge, is generated, and as a result, an adverse influence may occur on the process in some cases. Hence, since the exchange is too late when abnormal discharge occurs, the degree of wear of components must be detected before the generation of abnormal discharge. However, right before an abnormal discharge phenomenon occurs, every parameter of the apparatus normally works in many cases. Accordingly, heretofore, the exchange of components must be performed earlier.

In this example, the life of components can be estimated by detecting a discharge unstable region. In general, the discharge system has a discharge stable region and a discharge unstable region, and by changing discharge parameters such as pressure, type of gas, gas flow rate, and set electrical powers of an electrical source and a bias electrical source, the system may be placed in a discharge stable region or in a discharge unstable region. In the discharge unstable region, flameout or flicker of plasma, abnormal peak voltage Vpp of a high-frequency electrical source for plasma generation or variation thereof may be observed.

As shown in FIG. 11B, a general etching recipe is not set in an unstable region Rn but is only set in a stable region R1. Hence, the reason the abnormal discharge occurs is believed that the recipe which is originally set in the stable region may be transferred into the unstable region shown in FIG. 11B. Accordingly, in this example, after a recipe having a plurality of check steps is formed beforehand, the check steps of the recipe are sequentially executed using dummy wafers as workpieces, in which the check steps are prepared so as to transfer the discharge region from the stable region R1 into the unstable region Rn in a stepwise manner by changing the above discharge parameters in a stepwise manner.

As described above, the discharge unstable region has been known beforehand, and in addition, the unstable discharge can be detected. Hence, when the check steps of the recipe are sequentially executed, the transfer of the discharge unstable region can be detected. Since the reason for this transfer is believed that characteristics of the discharge system are changed, for example, by the wear of components, the life of components can be indirectly detected according to this method.

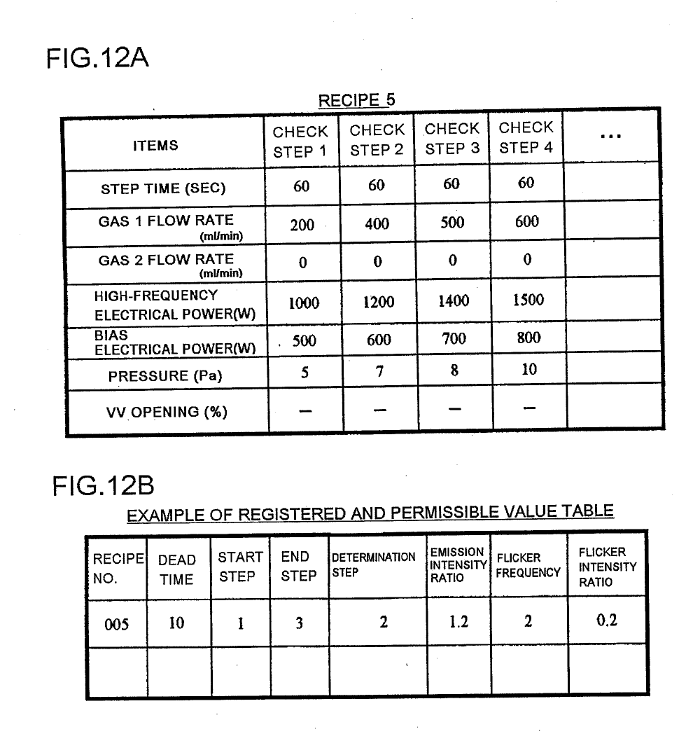

FIG. 12A shows a recipe (recipe 5) having check steps used in this example. When check steps 1 to 4 as shown in the figure are executed in that order, the discharge region is to be gradually transferred into the unstable region.

Hence, when a check step in which discharge becomes unstable is detected by performing the above check steps, the degree of wear of components can be indirectly checked.

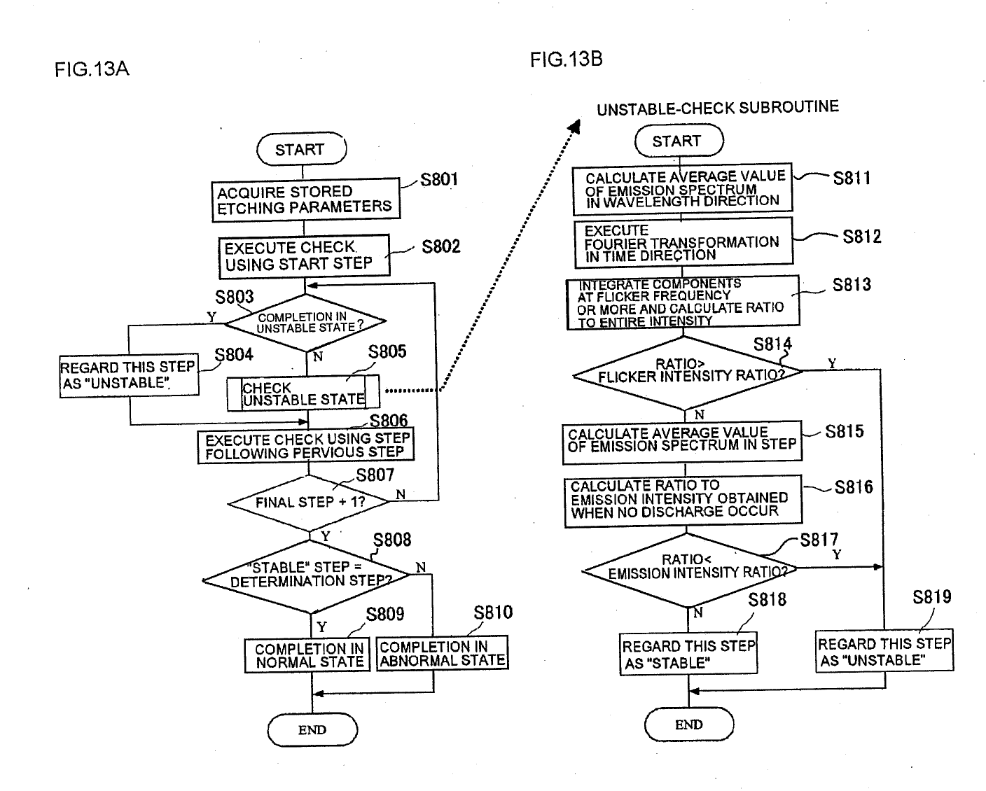

FIGS. 13A and 13B are flowcharts illustrating a process of this example. In Step S801, the apparatus parameters stored in the apparatus information database 102 are acquired, and check is started sequentially from step 1 shown in FIG. 12A. First, in Step S803, it is determined whether step 1 is completed in an abnormal state. When step 1 is completed in an abnormal state, in Step S804, it is determined that discharge is abnormal in step 1. When step 1 is completed in a non-abnormal state, in Step S805, it is determined whether the discharge is unstable (details of Step S805 will be described in Steps S811 to S819).

In Step S806, a check step following an immediately previous one is then executed, and when a final step is executed in Step S807, a check step in which the discharge becomes unstable is investigated. When the check step in which the discharge is unstable is changed, it is construed that the discharge condition is being changed, and a signal indicating abnormal is issued in Step S810.

Next, the detection of unstable discharge in Step S805 will be described. In the region in which the discharge is unstable, as described above, phenomena such as flicker, abnormal ignition, and flameout of plasma emission occur.

In the case of abnormal ignition of plasma, since the system detects this phenomenon as an error, subsequent steps are not further executed. Accordingly, when the error occurs, the step in which the error occurs is investigated, and subsequent steps are recorded as “unstable”.

Flicker of plasma may be detected by several methods and is detected in this example by flicker of light emission. When the emission spectrum value is Fourier-transformed in the time direction, the frequency component of variation in emission with time can be obtained. Of this variation component, when the value obtained by addition of intensities of frequency components, for example, of 2 Hz or more is a certain threshold value or more, it is determined that flicker occurs. In addition, in the case of flameout, since the average of the amount of emission is lower than that in a general case, the detection can be performed. As described above, when the ignition defect, flicker, and flameout are checked in every step, a step in which the unstable discharge occurs can be grasped.

In order to detect the unstable discharge, in Step S811, the average is first calculated by addition of the emission spectrum in the wavelength direction. The Fourier-transformation is performed in the time direction in Step S812, components at a flicker frequency or more are then integrated in Step S813, and the ratio to the entire intensity is then calculated. In Step S814, the above calculated ratio and the flicker intensity ratio (see FIG. 12B) set beforehand are compared with each other, and when the calculated value is larger, in this check step, the discharge is regarded as unstable.

In Step S814, when the above calculated ratio is not larger, in Step S815, the average of emission spectrum in the step is calculated, and the ratio to the emission intensity obtained when no discharge occurs is calculated. In Step S817, the calculated ratio and the emission intensity ratio (see FIG. 12B) which is set beforehand are compared with each other, and when the calculated ratio is smaller, in this check step, the discharge is regarded as unstable.

In this example, the unstable discharge is detected by the flicker of emission; however, in addition, the unstable discharge may be detected, for example, by checking apparatus parameters of discharge, such as abnormal Vpp voltage, drift thereof, high-frequency electrical power, abnormal tuning position of a bias voltage, or drift thereof.

### Example 6

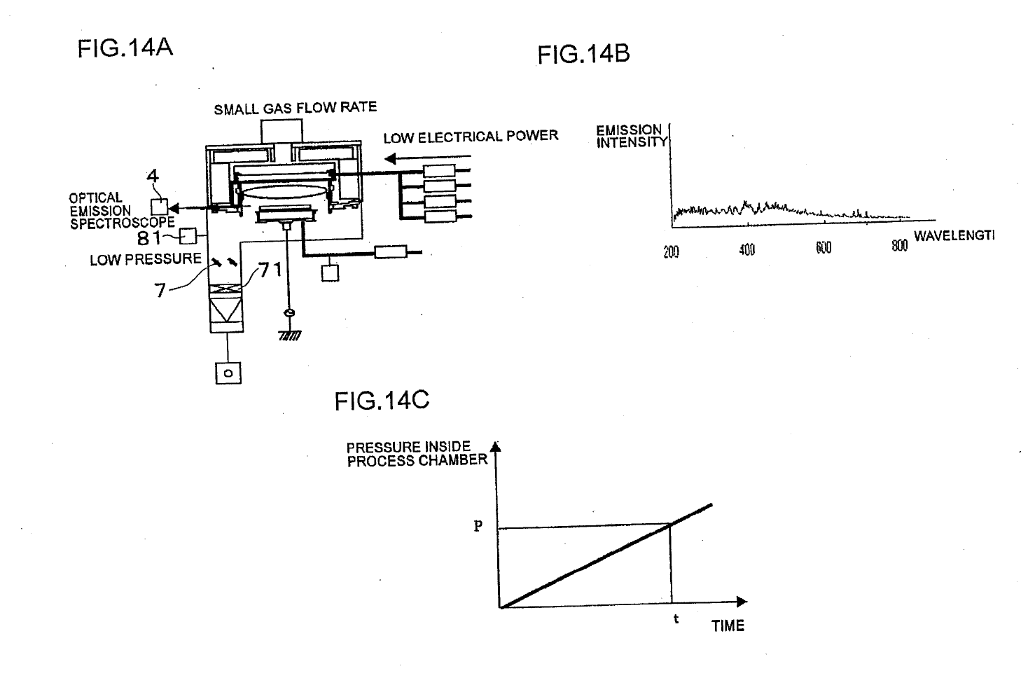

FIGS. 14A to 14C, 15A, 15B, and 16 are views illustrating diagnosis of the amount of a leak gas or that of an outgas of a sixth example according to the present invention. In this example, the amount of a leak gas in the process chamber or the amount of an outgas (the amount of a gas emitted from contents in the process chamber including the wall thereof) is obtained.

In general, when the amount of a leak gas or the amount of an out-gas is obtained, after the process chamber is evacuated for a predetermined period of time, as shown in FIG. 14C, the increase in pressure inside the process chamber is measured while an exhaust valve 71 is closed. When the measurement is carried out for a longer period of time, more precise measurement can be performed. However, in general, the amount of a leak gas and the amount of an outgas cannot be discriminated from each other.

According to this example, although being simple, a method is provided which is capable of detecting the increase in amount of a leak gas or that of an out-gas, and in addition, this method can determine one of the two types of gases, the amount of which is increased.

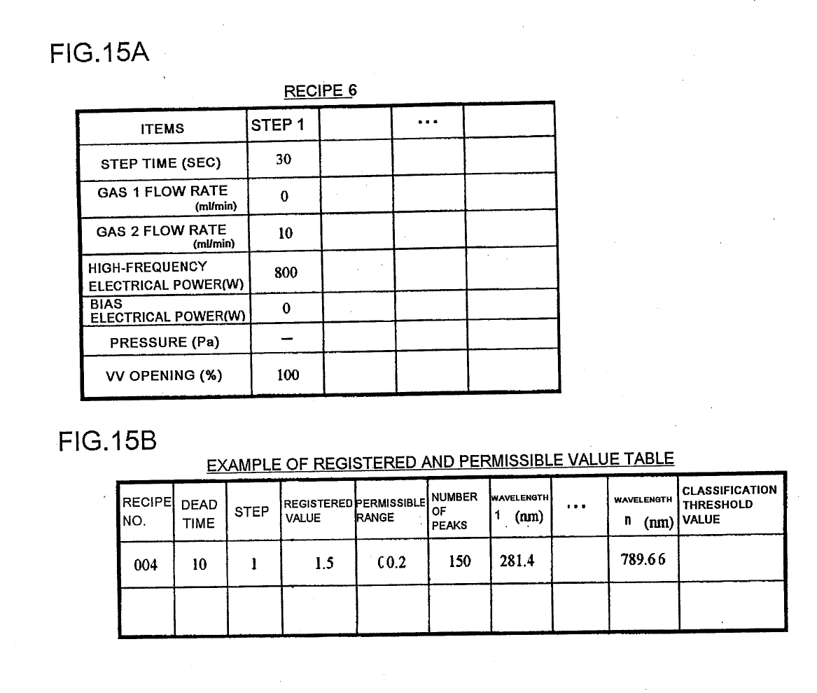

In this example, discharge is performed using a single element gas except nitrogen, oxygen, and hydrogen; however, experiments using the aforementioned gases are performed beforehand. In this experiment, as shown in FIG. 14A, the gas amount is decreased, the opening of the variable conductance valve 7 is increased, and the high-frequency electrical power for plasma generation is decreased, so that a very limit condition in which plasma cannot be ignited is researched. The very limit condition thus obtained is used as the diagnosis recipe (recipe 6, see FIG. 15A).

When the amount of a leak gas or that of an outgas is checked, discharge is performed using the recipe described above. In this case, when a leak gas or an out-gas is not present, plasma is not ignited; however, when a gas in a certain amount is present, plasma is ignited. In this example, depending on whether plasma is ignited or not, the amount of a leak gas or the amount of an out-gas is determined.

In addition, as shown in FIG. 14B, by analyzing this discharge spectrum, for example, when many spectra of N₂, H₂O, O, H, OH, N, O₂, and/or H₂ are observed, it is determined that the leak amount is large, and when many spectra of an etching gas, a film which is etched, a mask material and/or a compound thereof are observed, it is determined that the out-gas amount is large.

According to a related technique, a method has been proposed in which a spectrum in discharge is measured so as to determine whether leak occurs or not; however, when the leak amount is small, the S/N ratio is degraded by adverse influence of other emission spectra. On the other hand, in this example, since check is performed under the condition in which discharge hardly occurs, the entire emission intensity itself is small. Hence, the sensitivity of a spectrometer can be set high. Furthermore, since the ratio of the leak amount which contributes to discharge is high, the S/N ratio can be increased.

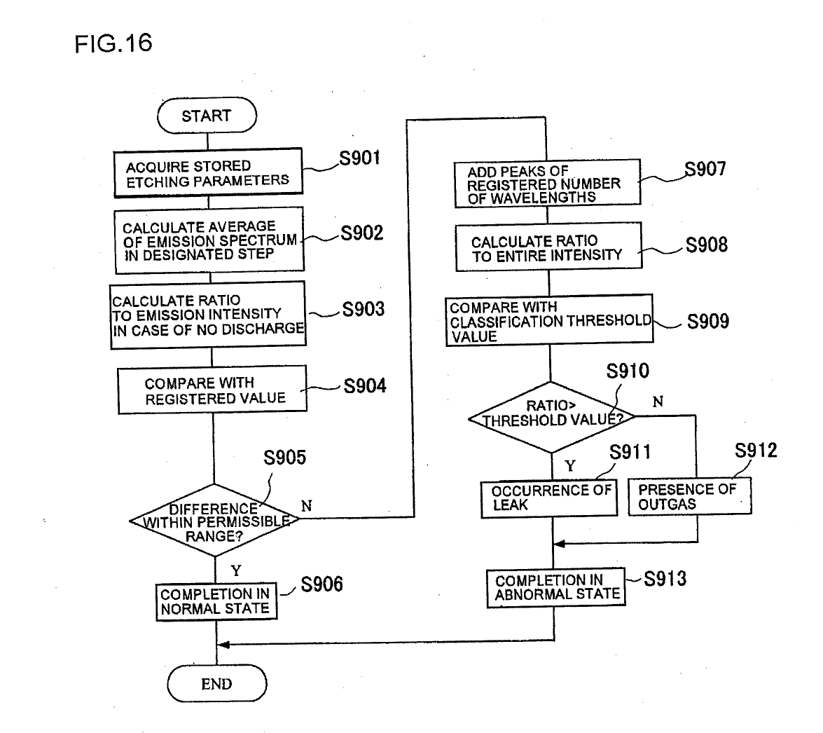

FIG. 16 is a flowchart illustrating a process of the diagnosis program. In Step S901, the apparatus parameters stored in the apparatus information database 102 are first acquired, and in Step S902, the average of the emission spectra in a step which is designated beforehand is calculated. In Step S903, the ratio to the emission intensity (light receiving intensity) obtained when no discharge occurs is calculated and is compared with the registered value shown in Table 15B in Step S904, and in Step S905, it is determined whether the different obtained by this comparison is within the permissible range or not. When the above difference is within the permissible range, the leak gas amount or the out-gas amount is determined to be normal, and the process is completed.

When the difference is outside the permissible range, in Step S907, peaks values of registered number of wavelengths of the emission spectra are added, (for example, when the leak gas amount is to be determined, values of a plurality of peaks of emission spectrum of a nitrogen gas are added). In Step S908, the ratio between the value thus obtained by addition and the entire intensity is calculated, and in Step S909, the ratio is compared with a classification threshold value. In Step S910, it is determined whether the ratio is larger than the classification threshold value or not. When the ratio is larger than the classification threshold value, it is determined in Step S911 that the leak gas exists, and when the ratio is not larger than the classification threshold value, it is determined in Step S912 that the outgas exists. In Step S913, a signal indicating abnormal leak gas amount or outgas amount is issued.

### Example 7

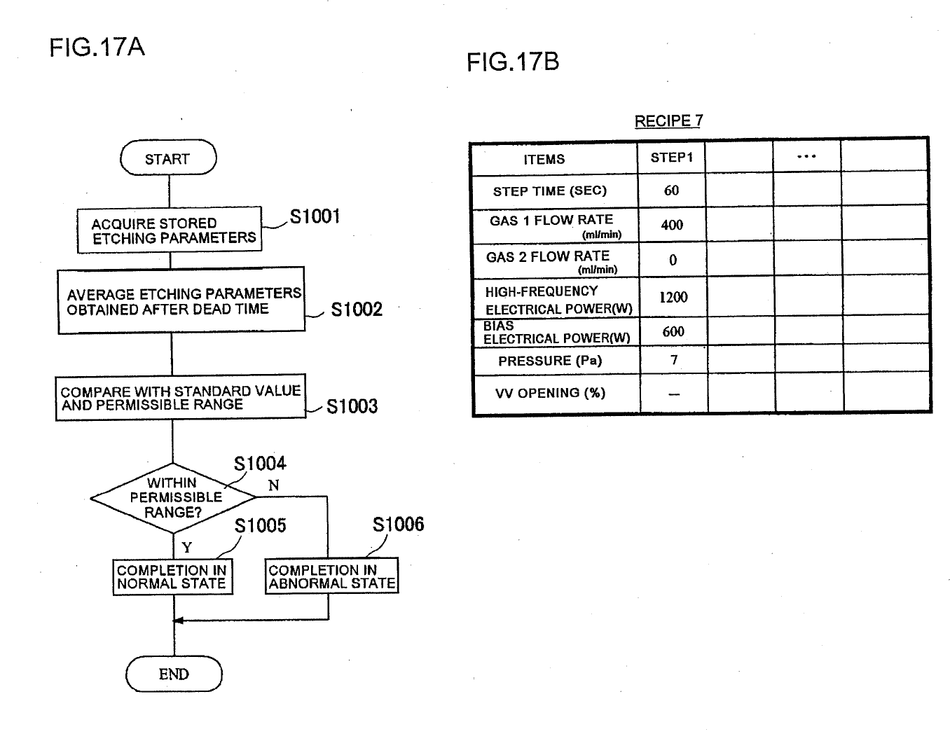

FIGS. 17A and 17B are views illustrating diagnosis of the amount of the change in apparatus parameter of a seventh example according to the present invention.

Respective parameters of etching are gradually changed as the number of processed wafers is increased. For example, since reflecting plasma impedance, the Vpp voltage is changed, for example, by deposition of reaction products in the process chamber and the degree of wear of components. In a manner similar to that described above, the tuning point of the high-frequency electrical source is also changed.

The values of the respective process parameters of etching which are obtained when the amount of deposition of reaction products is small in the apparatus are recorded as standard values. The permissible ranges are set with respect to the standard values, and when the respective parameters obtained when the process is performed under the same condition are outside the ranges, the process is determined to be abnormal.

Heretofore, the method as described above has been applied to an etching process for production; however, in actual etching, as the etching proceeds, respective parameters themselves are considerably changed. In addition, in the case of multi-product production, there has been a problem in that the standard value and the permissible value are difficult to set for each product.

In this example, since the check is not performed for product wafers but for dummy wafers, the apparatus condition is stable when the measurement is performed. In addition, since the products are not processed, the number of recipes used for the check can be reduced.

As the recipe, a normal etching condition may be used; however, in order to more sensitively detect the change in condition of the apparatus, check is preferably performed using a recipe having a very limit condition as described in Example 5 in which the discharge is barely in a stable region.

FIG. 17A is a flowchart illustrating a process of the diagnosis program. First, in Step S1001, the process parameters stored in the apparatus information database 102 are acquired, and the etching parameters obtained after the dead time are averaged in Step S1002 and are then compared with the respective permissible ranges based on the standard values in Step S1003. In Step S1004, it is determined whether the average is within the corresponding permissible range or not, and when the average is not therein, a signal indicating abnormality is issued.

### Example 8

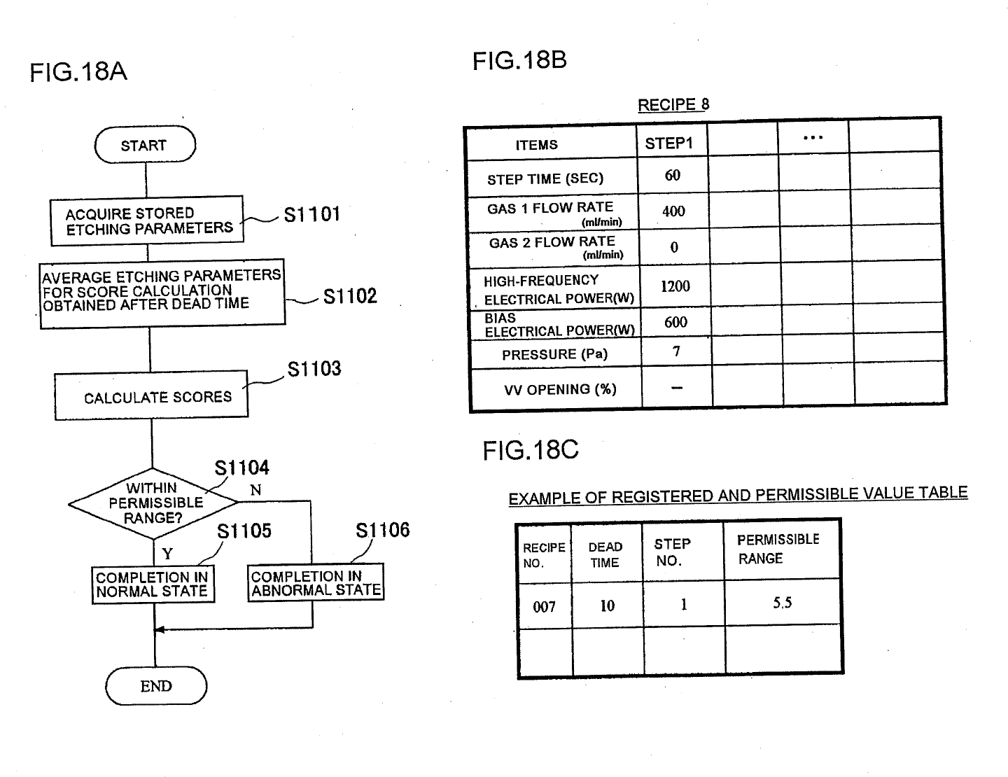

FIGS. 18A to 18C, 19, and 20 are views illustrating diagnosis of the amount of change in total apparatus parameter of an eighth example according to the present invention.

In general, the change in apparatus with time which is apparently observed is generally a very small change in many cases. In actual etching for production, since the change in condition itself of the apparatus caused by the progress of etching is significant, it is difficult to detect the change in apparatus. In addition, since various many parameters are simultaneously and gradually changed, even when the parameters are individually checked as described in Example 7, the changes thereof are small, and hence the change in condition may not be precisely grasped in some cases.

In this example, arithmetic processing is performed for the entire parameters of the apparatus, and from the calculation results, the change in apparatus is detected. When the diagnosis is performed, the entire parameters of the apparatus when it is in the initial state are recorded beforehand and are set to standard values. In this case, in order to place the apparatus in a predetermined state, dummy wafers are used. In addition, as the process conditions, since the change may not be easily observed under normal stable conditions, a recipe having the very limit condition of Example 5 (see recipe 8 shown in FIG. 18B) is used in which discharge is barely in a stable region. Next, by using an apparatus which requires maintenance, the entire parameters are also obtained under the same conditions as performed before.

The two types of entire parameters thus obtained are compared with each other, and the differences of respective parameters are measured. In this case, since the amount of change may have a minus or a plus sign with respect to the standard value, the absolute value thereof is used. Next, all the amounts of change are normalized to have the same value. In particular, coefficients are obtained so that all the amounts of change have a predetermined value, such as 1. However, according to this calculation, a parameter having a smaller amount of change has a larger coefficient. As a result, a mere noise may be regarded as a significant change in some cases, and hence the amount of change to a certain level or less must be ignored. For this purpose, for example, additional process is also performed such that a parameter having a small change such as 1% or less of the full scale is excluded from the calculation.

After the pre-treatment described above is performed, the actual check is then performed. In this case, between processes performed for products, a dummy wafer is used, and discharge process is performed using the recipe (recipe 8) exclusive therefor.

After the process is performed, as for parameters which showed the changes in experiment performed beforehand, the differences from the standard values are obtained and are then added. When the value thus obtained reaches a certain predetermined value or more, a process such as issue of an alarm is performed.

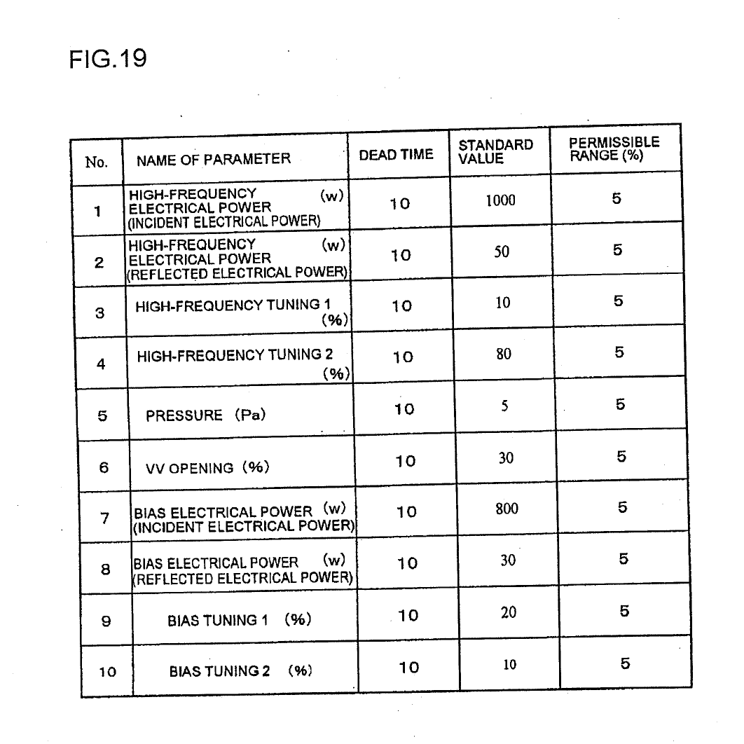

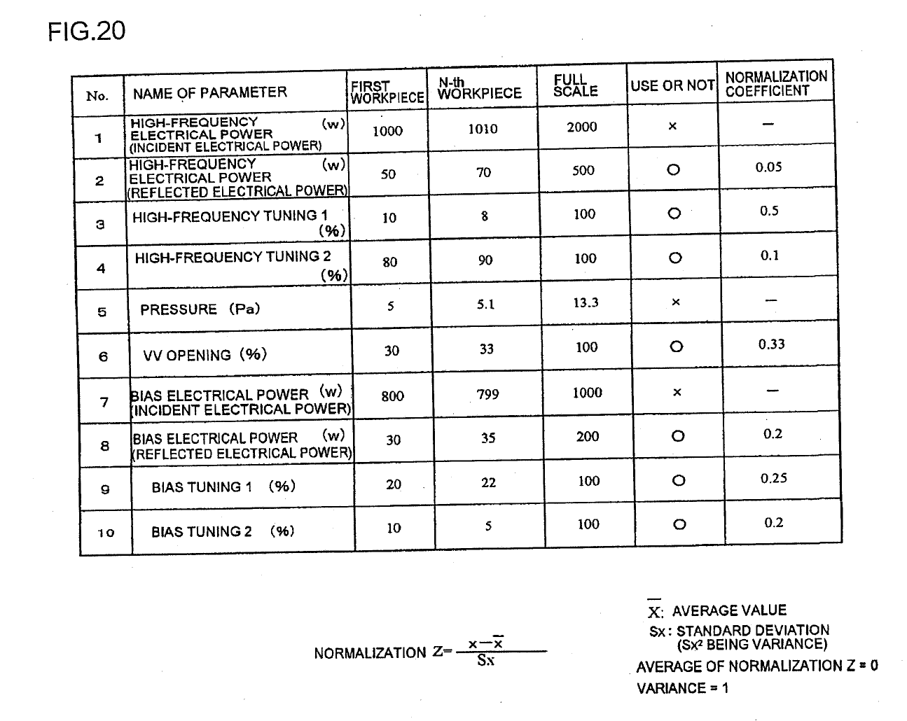

FIGS. 19 and 20 are tables showing parameters for counting score. The column of the parameter name in the table is an example of an etching parameter to be checked.

First, the parameters obtained in the state in which the number of processed wafers is small and the parameters right before maintenance obtained using the recipe 8 are recorded (columns named “first wafer” and “n-th wafer”). The differences therebetween are calculated, and the use of the individual parameters is determined depending on whether the value thus obtained is 1% or more of the full scale or not.

In particular, although the difference in high-frequency incident electrical power in this table is 10 W, since the full scale is 2,000 W, the change is only 0.5%. As a result, this parameter is not employed. By the same calculation as described above, parameters provided with 0 in the employment column in the table are selected. Since being different from each other in terms of physical value and/or full scale, these amounts of changes cannot be discussed on the same level, and hence the normalization is performed.

In detail, the high-frequency reflected electrical power has a change of −20 W. Since the change has a plus or minus sign, an absolute value of 20 is used. Since the maximum change is 20, in order to normalize it to 1, the normalization coefficient is set to 0.05. For example, when this parameter is change by 10 W, by multiplying 0.05 which is the normalization coefficient, 0.5 is obtained. Hereinafter, this value is called a score of this parameter.

Accordingly, the scores of the respective parameters are each in the range of 0 to 1. When the number of parameters employed in this case is assumed to be m, the total of the scores is in the range of 0 to m. By periodically executing the recipe 8, the total score is calculated. When this value exceeds the permissible range, the process is determined to be abnormal. When the permissible range is set to a value of m/2 by way of example, when an abnormal case occurs, it is considered that the apparatus is approximately in the state between the state of the first wafer and the state right before the maintenance. In this example described above, the case is described in which extraction of parameters is performed by a hand work; however, when a method of multivariate analysis such as a principle component analysis is used, the characteristics of the change can also be extracted.

FIG. 18A is a flowchart illustrating a process of the diagnosis program. In Step S1101, the apparatus parameters stored in the apparatus information database 102 are acquired, etching parameters for score calculation obtained after the dead time are normalized in Step S1102, and the total of the scores is calculated in Step S1103. In Step S1104, it is determined whether the total of the scores is within the permissible range shown in FIG. 18C or not, and when the total is outside the permissible range, a signal indicating abnormality is issued.

### Example 9

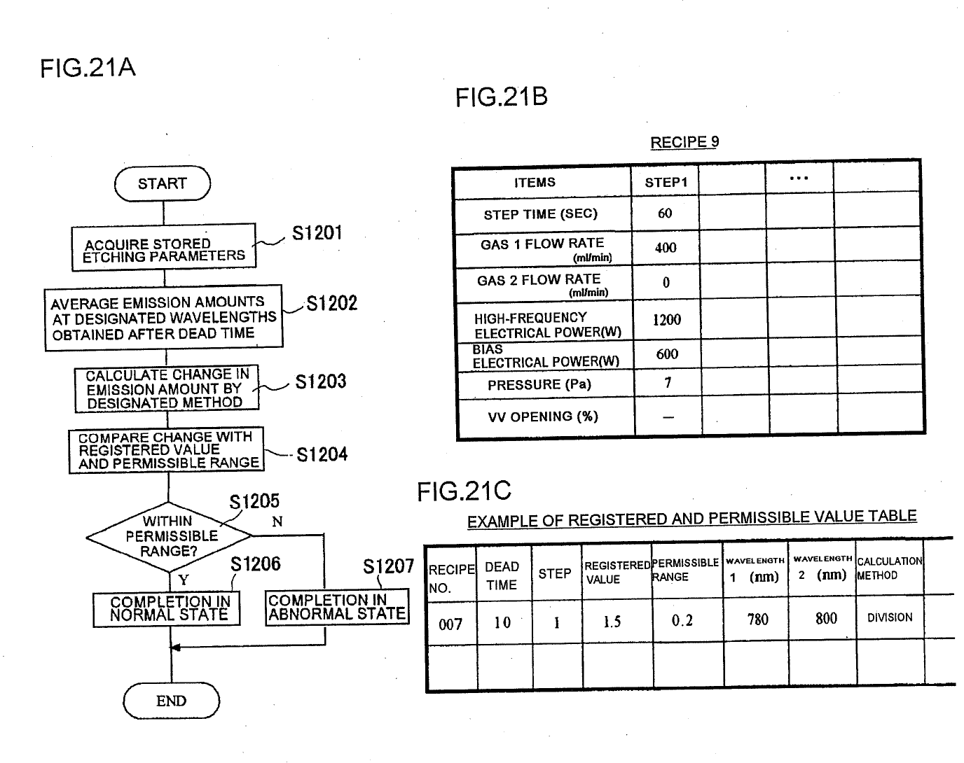

FIGS. 21A to 21C are views illustrating diagnosis of the amount of change in emission of a ninth example according to the present invention. In etching, complicated reaction occurs among an etching gas, a film to be etched, and a mask material, and the condition of the reaction is shown in the plasma emission.

Accordingly, when a wavelength having a close relationship with properties of an etching process is extracted from the plasma emission and monitored, the etching properties can be estimated. Heretofore, the emission condition in etching is checked; however, in the case of multi-product production, since the emission condition is changed from product to product, the change cannot be grasped. However, in this example, since dummy wafers are used, and the comparison of emission can be performed under the same condition (using the same recipe 8), the change with time can be easily grasped. In addition, as the dummy wafer, since a wafer provided with an oxide film, a wafer provided with a resist, or the like may be used in addition to a normal silicon wafer, emission monitoring associated with various processes can be performed.

FIG. 21A is a flowchart illustrating a process of the diagnosis program. In Step S1201, the apparatus parameters stored in the apparatus information database 102 are acquired, the averages of the emission amounts of designated wavelengths obtained after the dead time are calculated in Step S1202, and the change between the emission amounts is calculated by a designated method in Step S1203. In Step S1204, the change in amount thus obtained is compared with the permissible range based on the registered value shown in FIG. 12C. In Step S1205, it is determined whether the change in amount is within the permissible range shown in FIG. 21C or not, and when it is outside the permissible range, a signal indicating abnormality is issued.

Heretofore, the nine examples have been individually described, and in practical operation, when a lot (dummy lot) only composed of dummy wafers is prepared, and the diagnosis recipes shown in the above examples and the diagnosis programs associated with the recipes are allocated to the respective dummy wafers, for example, by processing the dummy lot once per day, most of preventive maintenance operations can be completed.

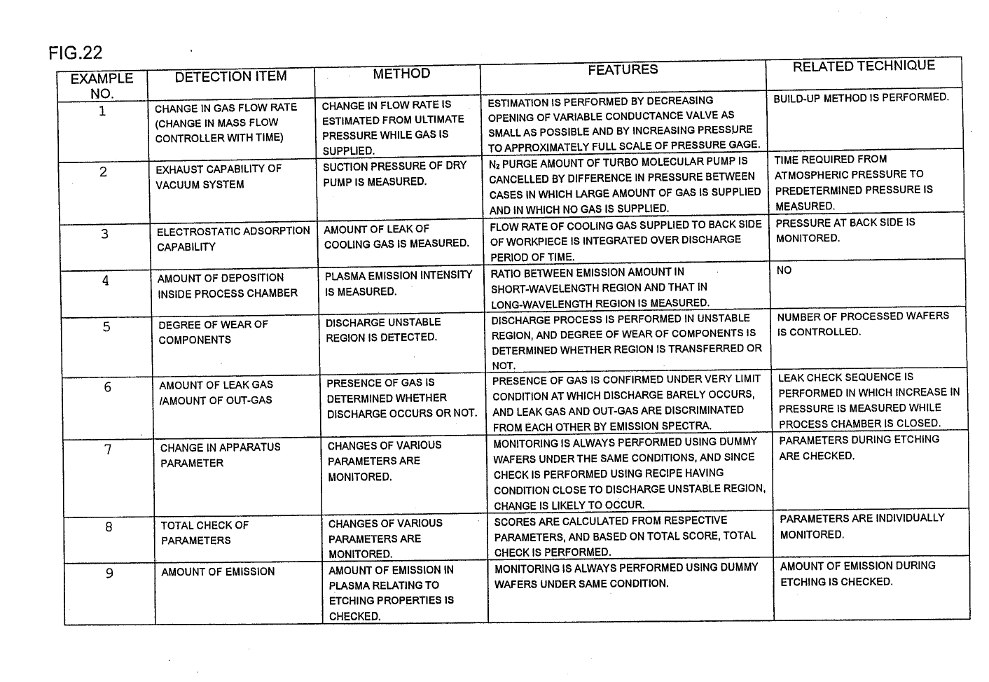

FIG. 22 is a table summarizing the above examples.

1. A method for performing a plasma process using a plasma processing apparatus which comprises:
a vacuum process chamber;
an exhaust device evacuating the vacuum process chamber;
a mass flow controller supplying a process gas into the vacuum process chamber;
a stage electrode receiving a workpiece in the vacuum process chamber and holding the workpiece by adsorption;
a transfer device placing the workpiece on the stage electrode and taking out the workpiece after the workpiece is processed; and
a high-frequency electrical source;
wherein the plasma process is performed for the workpiece with plasma generated by applying a high-frequency electrical power from the high-frequency electrical source to the supplied process gas;
wherein the method comprises:
a first step of performing the plasma process for the workpiece in the vacuum process chamber by a corresponding recipe of predetermined recipes; and
a second step of acquiring apparatus parameters showing the condition of the plasma processing apparatus when a specific recipe of the predetermined recipes is executed to diagnose whether the condition of the plasma processing apparatus is good or not based on the acquired apparatus parameters;
wherein the apparatus controller comprises a diagnosis device which acquires a plurality of recipes, one of the plurality of recipes corresponding to the workpiece and being applied for processing of the workpiece, and wherein apparatus parameters of the plasma processing apparatus are acquired when a specific recipe of the plurality of recipes is executed, the diagnosis device diagnosing whether the condition of the plasma processing main frame is good or not based on the acquired apparatus parameters;
wherein the specific recipe is a recipe having at least one process condition different from a process condition under which normal operation is performed;
wherein the at least one process condition of the specific recipe is a process for supplying a predetermined amount of a gas into the vacuum process chamber via the mass flow controller and setting an exhaust speed of the exhaust device so that the pressure inside the process chamber becomes close to a full scale level of a pressure gage;
wherein the setting of the exhaust speed of the exhaust device includes controlling an opening amount of an exhaust value of the exhaust device; and
wherein the diagnosis device compares an ultimate value of the gas pressure inside the vacuum process chamber as measured by the close to the full scale level of the pressure gage based upon the predetermined amount of the gas supplied with a registered value of the pressure gage to diagnose whether the condition of the plasma processing main frame is good or not.

2. The method for performing a plasma processing according to claim 1, wherein the specific recipe is a recipe having a process condition different from a process condition under which normal operation is performed.

3. The method for performing a plasma processing according to claim 1, wherein the second step diagnoses the condition of the plasma processing apparatus based on a diagnosis program associated with the specific recipe and issues an alarm when the diagnosis program determines that the condition of the plasma processing apparatus is not good.

4. The method for performing a plasma processing according to claim 1,
wherein the specific recipe has a step of supplying a predetermined amount of a gas into the vacuum process chamber via the mass flow controller; and
wherein the second step diagnoses the condition of the plasma processing apparatus by comparing an ultimate value of a gas pressure in the vacuum process chamber with a registered value.

5. The method for performing a plasma process according to claim 1,
wherein the exhaust device comprises a turbo molecular pump and a dry pump provided at an exhaust side of the turbo molecular pump;
wherein the specific recipe has a step of supplying no gas into the vacuum process chamber and a step of supplying a gas into the vacuum process chamber; and
wherein the second step diagnoses the condition of the plasma processing apparatus based on the difference between the pressure at the exhaust side of the turbo molecular pump in the step of supplying no gas and the pressure at the exhaust side of the turbo molecular pump in the step of supplying a gas.

6. The method for performing a plasma process according to claim 1,
wherein the plasma processing apparatus further comprises cooling gas supply means for supplying a cooling gas between the stage electrode and the workpiece held thereon by adsorption; and
wherein the second step diagnoses whether a holding state by adsorption between the workpiece and the stage electrode is good or not by comparing a result obtained by integration of a flow rate of the cooling gas with a registered value.

7. The method for performing a plasma processing according to claim 1,
wherein the second step measures the emission intensity of plasma, and diagnoses whether the amount of a reactor product deposited in the vacuum process chamber is appropriate or not based on a ratio between measured emission intensity in a short-wavelength region and measured emission intensity in a long-wavelength region.

8. The method for performing a plasma processing according to claim 1,
wherein the specific recipe has a step of changing a condition for generating plasma in the vacuum process chamber; and
wherein the second step diagnoses a degree of wear of a component in the vacuum process chamber based on an emission intensity of plasma generated under a changed condition and apparatus parameters relating to discharge.

9. The method for performing a plasma processing according to claim 1,
wherein the second step diagnoses whether the amount of a gas leaking into the vacuum process chamber or the amount of an outgas generated from contents in the vacuum process chamber is appropriate or not based on emission spectra of N₂, H₂O, H, OH, N, O₂, and/or H₂ included in a measured emission spectrum of plasma.

10. The method for performing a plasma process according to claim 1,
wherein the second step diagnoses whether the condition of the plasma processing apparatus is good or not based on the accumulation of differences between apparatus parameters which are acquired after the apparatus is initialized and apparatus parameters acquired after operation is performed for a predetermined period of time.
